(19) United States
(12) Patent Application Publication
(10) Pub. No.: US 2009/0205564 A1
(43) Pub. Date: Aug. 20, 2009

(54) Crystal-growing furnace system

(75) Inventors: Shiow-Jeng Lew, Taipei (TW); Hur-Lon Lin, Taipei (TW)

Correspondence Address: BACON & THOMAS, PLLC, 625 SLATERS LANE, FOURTH FLOOR, ALEXANDRIA, VA, 22314-1176, US

(73) Assignee: Green Energy Technology Inc., Taipei (TW)

(21) Appl. No.: 12/213,311

(22) Filed: Jun. 18, 2008

(30) Foreign Application Priority Data
Feb. 19, 2008 (TW) 097105738

(51) Int. Cl. C30B 35/00

(52) U.S. Cl. 117/206

(57) ABSTRACT

A crystal-growing furnace system includes an isolated chamber, a furnace upper body, and a controller room, wherein the isolated chamber and the controller room are arrayed and isolated from each other. A door is provided between the controller room and the isolated chamber so as to isolate or communicate the controller room from or with the isolated chamber. The isolated chamber includes, among others, a top board, a furnace lower body, and a lifting device, wherein the lifting device moves the furnace lower body upward and closes the furnace upper body so as to form an enclosed crystal-growing furnace, or downward and departs from the furnace upper body. Because the isolated chamber and the controller room are arranged isolating from each other, noise, high temperature, and dust pollution can be isolated from the isolated room, so that personnel working in the controller room can be assured of safety and health. Moreover, since the furnace upper body is arranged outside of the isolated chamber, heat can be transpired directly to the atmosphere, without the need of huge air conditioning devices for cooling factory, and thus having merits both on energy saving and safety.

### BACKGROUND OF THE INVENTION

1. Field of the Invention

The present invention relates to a crystal-growing furnace, more particularly, to a crystal-growing furnace system.

2. Description of Related Art

Referring to FIG. 1, a schematic view illustrating a conventional crystal-growing furnace system, a plurality of crystal-growing furnaces 91 and a controller room 92 are located together in a sealed factory 9. When the furnaces 91 are operated, high temperature will be incurred and pure water needs to be supplied to the space between inner wall and outer wall of each furnace 91. However, a great amount of pure water requires a purifier 96 to provide purification of water. In addition, a chiller 97 and cooling towers 94 are employed to cool the pure water contained in a reservoir 95. Moreover, in order to fit personnel working in the factory 9 so as to control the furnaces 91, a huge air conditioning device 93 is required for cooling heat produced by the furnaces 91 and for lowering the temperature inside the factory. As a result, cost for establishing and maintaining the cooling equipment is considerably high, let alone the electrical energy consumed during operation of the crystal-growing furnaces.

Further, because the crystal-growing furnaces 91 are all disposed in the factory, operators will suffer in a long period from noise caused duration operation and pollution produced from graphite particles, and this will adversely affect health of the operators. In case a public accident occurs, for instance, the crystal-growing furnace 91 explodes, since there are no isolating or shielding facilities in the factory, such a disaster will make the factory and personnel suffer a great loss.

### SUMMARY OF THE INVENTION

The present invention is to provide a crystal-growing furnace system, comprising an isolated chamber, a furnace upper body, and a controller room.

According to the present invention, the isolated chamber includes a top board and a sidewall, wherein the top board is provided with an opening. The isolated chamber is arranged with a furnace lower body and a lifting device, wherein the furnace lower body is provided with an upper opening, and the lifting device is provided for selectively moving the furnace lower body upward such that the upper opening gets close to the opening of the top board, or downward and departs from the opening of the top board.

The furnace upper body is arranged above the top board of the isolated chamber, and is provided with a lower opening which matches, correspondingly, the opening of the top board.

The controller room is located beside and neighboring to the sidewall of the isolated chamber, where a door is provided on the sidewall. The door is selectively closed or opened so as to isolate the controller room from the isolated chamber when closed, or to communicate the controller room with the isolated chamber when opened.

According to the present invention, because a crystal-growing furnace is arranged inside the isolated chamber, the isolated chamber and the controller room are isolated from each other. As such, noise, high temperature, and dust pollution can be isolated from the isolated room, so that personnel working in the controller room can be assured of safety and health. Moreover, since the furnace upper body is arranged outside of the isolated chamber, heat can be transpired directly to the atmosphere. Neither the high temperature incurred by the furnace will affect the personnel in the controller room. Therefore, it is not necessary to prepare huge air conditioning devices for cooling the factory, and that expenses on the air conditioning devices and on electricity fees can be greatly saved. Further, the crystal-growing furnaces are each spaced apart and isolated from one another. Therefore, even if public accident occurs in a particular furnace, other furnaces will not be affected. Apparently, the crystal-growing furnace system, according to the present invention, has merits both on energy saving and safety.

Further, a reinforced ring is provided around circumference of the opening of the top board at the isolated chamber. The top board includes a reinforced concrete frame which is cured after grouting of concrete slurry so as to reinforce the structure of the whole top board. The isolated chamber may include another sidewall on which an air cleaner is provided. When crystal growth is finished and the furnace lower body is opened, heat and dust will be released from the furnace to the isolated chamber. At this moment, the air cleaner is turned on. Until the air in the isolated chamber is cleaned and the temperature is lowered, the door is then opened for discharging crystal ingots and for loading next batch of silicon material. As such, the controller room will not be polluted. The air cleaner serves to filter and exhaust air out of the isolated room and to filter and draw outside air into the isolated room.

The lifting device arranged in the isolated room includes at least one vertical screw, at least one nut, at least one universal link, and a driving source. The at least one nut is engaged, correspondingly, with the at least one vertical screw. The driving source rotates the at least one universal link so as to rotate the vertical screw and to move the furnace lower body.

Further, a heating room is arranged inside the crystal-growing furnace, where the heating room includes an upper partition, a plurality of side partitions, and a lower partition. The plural side partitions are arrayed around and assembled beneath the upper partition, which are then fixed together to the furnace upper body; whereas the lower partition is fixed to the furnace lower body. The heating room accommodates at least one heater. The heating room has a double-layer structure including an inner insulation layer and an outer warm-keeping layer.

According to the present invention, the furnace upper body includes an upper furnace wall cooling assembly, which, preferably, refers to a spray cooling assembly, for dispersing heat directly to the atmosphere. The furnace lower body includes a lower furnace wall cooling assembly, which, preferably, refers to a spray cooling assembly. As such, there is no need to set up chillers, cooling towers, and purifiers, and expenses on facilities and maintenance can be saved.

Other objects, advantages, and novel features of the present invention will become more apparent from the following detailed description when taken in conjunction with the accompanying drawings.

### BRIEF DESCRIPTION OF THE DRAWINGS

FIG. 1 is a schematic view illustrating a conventional crystal-growing furnace;

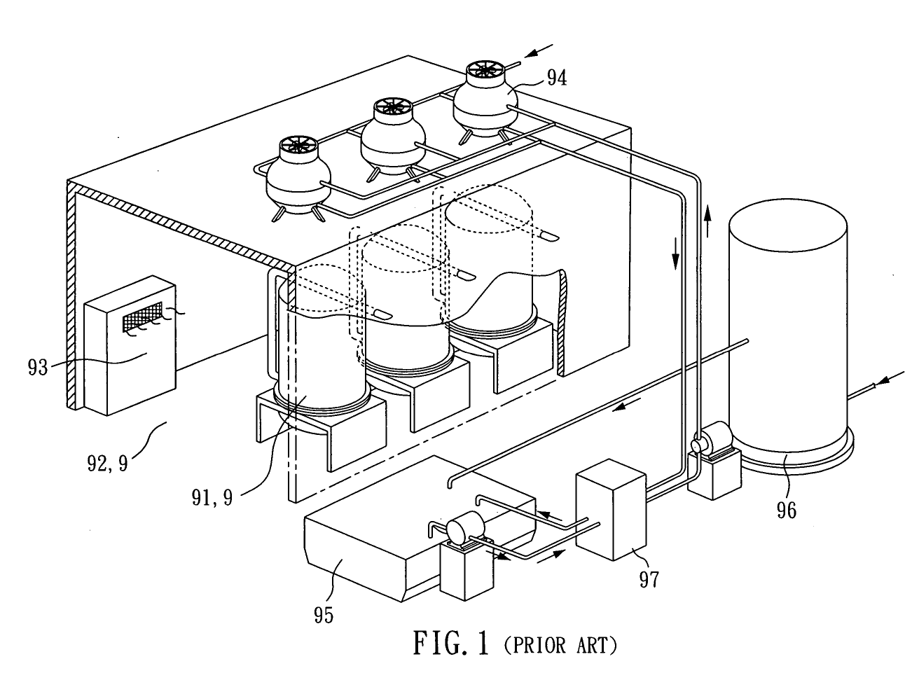

FIG. 2 is a schematic view illustrating a crystal-growing furnace system according to a first embodiment of the present invention;

FIG. 3 is a cross-sectional view illustrating part of the crystal-growing furnace system according to the first embodiment of the present invention;

FIG. 4 is a schematic view illustrating a furnace lower body departing from the opening of a top board according to the first embodiment of the present invention;

FIG. 5 is a perspective view illustrating the furnace lower body getting close to the opening of the top board according to the first embodiment of the present invention;

FIG. 6 is a schematic view illustrating a crystal-growing furnace system according to a second embodiment of the present invention; and

FIG. 7 is a schematic view illustrating a crystal-growing furnace system according to a third embodiment of the present invention.

### DETAILED DESCRIPTION OF THE PREFERRED EMBODIMENTS

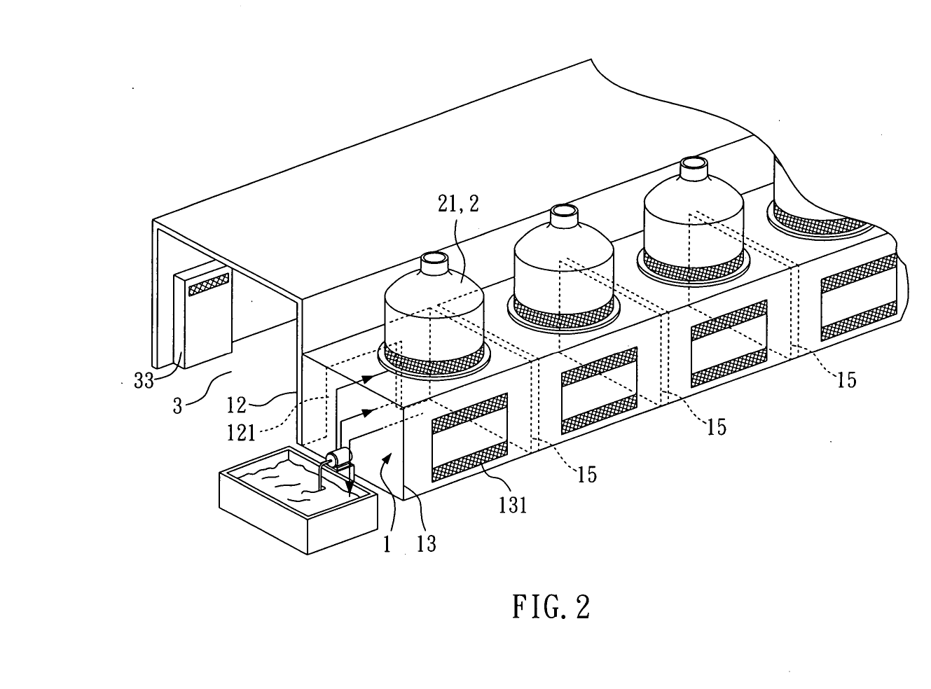

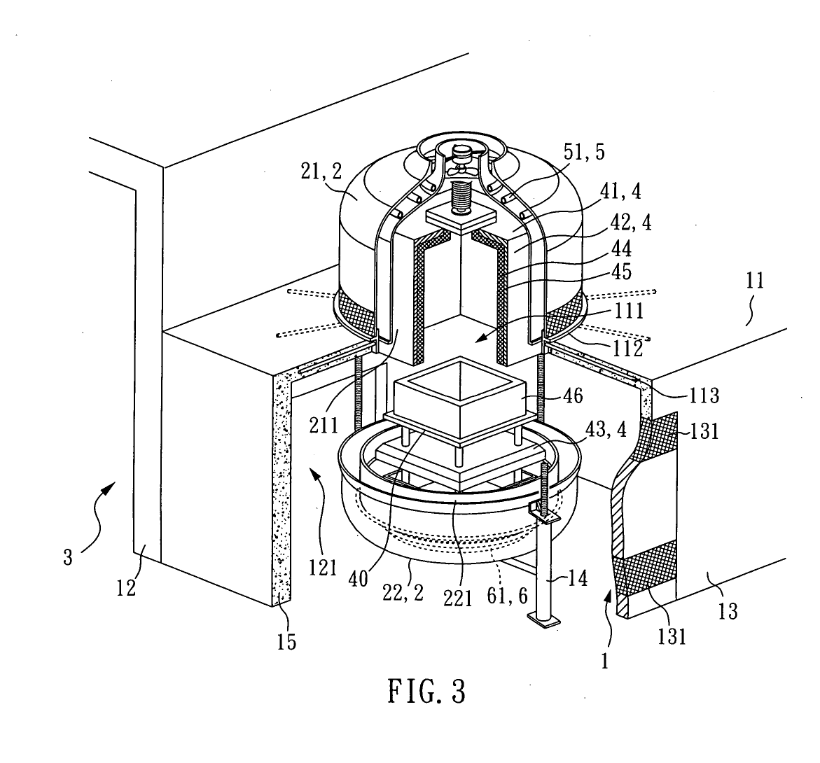

Referring to FIGS. 2 and 3, a schematic view illustrating a crystal-growing furnace system according to the present invention and a cross-sectional view illustrating part of the crystal-growing furnace system, the crystal-growing furnace system comprises an isolated chamber 1, a furnace upper body 21, and a controller room 3.

The isolated chamber 1 includes a top board 11 and a sidewall 12, wherein the top board 11 is provided with an opening 111, and includes a reinforced concrete frame 113 which is cured after grouting of concrete slurry so as to reinforce the structure of the whole top board 11. A reinforced ring 112 is provided around the circumference of the opening 111, wherein the reinforced ring 112 is welded to the reinforced concrete frame 113.

The isolated chamber 1 is arranged with a furnace lower body 22 and a lifting device 14, wherein the furnace lower body 22 is provided with an upper opening 221, and the lifting device 14 is provided for selectively moving the furnace lower body 22 upward such that the upper opening 221 gets close to the opening 111 of the top board 11, or downward and departs from the opening 111.

The furnace upper body 21 is arranged above the top board 11 of the isolated chamber 1, and is provided with a lower opening 211 which matches, correspondingly, the opening 111 of the top board 11. When the furnace lower body 22 is moved upward by the lifting device 14, the upper opening 221 can get closer to and beneath the opening 111 so as to be assembled with the furnace upper body 21 into a crystal-growing furnace in which a furnace inner space is formed.

The controller room 3 is located beside and neighboring to the sidewall 12 of the isolated chamber 1, where a door 121 is provided on the sidewall 12. The door 121 is selectively closed or opened so as to isolate the controller room 3 from the isolated chamber 1 when closed, or to communicate the controller room 3 with the isolated chamber 1 when opened.

Because the crystal-growing furnace 2 is arranged in the isolated chamber 1, the isolated chamber 1 and the controller room 3 are isolated from each other. As such, noise, high temperature, and dust pollution can be isolated from the isolated room 1, so that personnel working in the controller room 3 can be assured of safety and health. Moreover, since the furnace upper body 21 is arranged outside of the isolated chamber 1, heat can be transpired directly to the atmosphere. Neither the high temperature incurred by the furnace 2 will affect the personnel in the controller room 3. Therefore, it is not necessary to prepare huge air conditioning devices for cooling the factory, and that expenses on the air conditioning devices and on electricity fees can be greatly saved.

As shown in FIG. 2, the crystal-growing furnaces 2 are each spaced apart and isolated from one another by sidewalls 15. Therefore, even if public accident occurs in a particular furnace 2, other furnaces 2 will not be affected. Apparently, the crystal-growing furnace system, according to the present invention, has merits both on energy saving and safety. Further, referring to FIGS. 2 and 3, the isolated chamber 1 includes another sidewall 13 on which an air cleaner 131 is provided. When crystal growth is finished and the furnace lower body 22 is opened, heat and dust will be released from the furnace 2 to the isolated chamber 1. At this moment, the air cleaner 131 is turned on. Until the air in the isolated chamber 1 is cleaned and the temperature is lowered, the door 121 is then opened for discharging crystal ingots and for loading next batch of silicon material. As such, the controller room 3 will not be polluted. The air cleaner 131 serves to filter and exhaust air out of the isolated room 1 and to filter and draw outside air into the isolated room 1.

Referring to FIG. 3, a heating room 4 is arranged inside the crystal-growing furnace 2, where the heating room 4 includes an upper partition 41, four side partitions 42, and a lower partition 43. The four side partitions 42 are arrayed around and assembled beneath the upper partition 41, which are then fixed together to the furnace upper body 21; whereas the lower partition 43 is fixed to the furnace lower body 22. As a result, the lower partition 43 can move upward along with the furnace lower body 22 and seal, correspondingly, with underneath of the four side partitions 42. The heating room 4 accommodates at least one heater 40 to heat the crystal material in a crucible 46. The heating room 4 has a double-layer structure including an inner insulation layer 44 and an outer warm-keeping layer 45.

As shown in FIG. 3, the furnace upper body 21 includes an upper furnace wall cooling assembly 5, which, preferably, refers to a spray cooling assembly 51, for dispersing heat directly to the atmosphere. The furnace lower body 22 includes a lower furnace wall cooling assembly 6, which, preferably, refers to a spray cooling assembly 61. As such, there is no need to set up chillers, cooling towers, and purifiers, and expenses on facilities and maintenance can be saved.

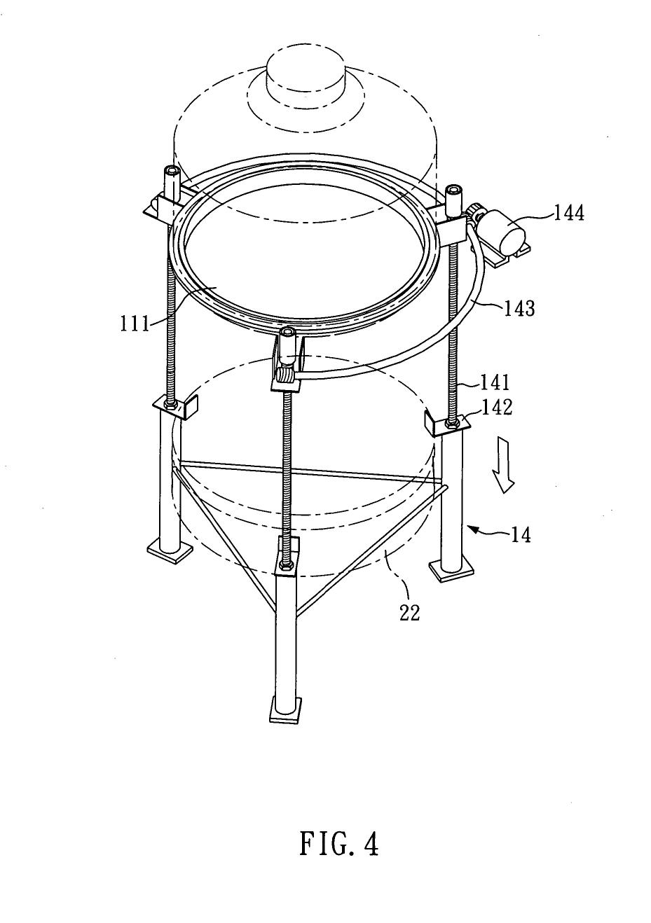

Further, referring to FIG. 4, a schematic view illustrating the furnace lower body 22 departing from the opening of the top board 11 according to the first embodiment of the present invention, the lifting device 14 includes three vertical screws 141, three nuts 142, a universal link 143, and a driving source 144. The three nuts 142 are welded to furnace lower body 22, respectively, and are engaged with the three vertical screws 141. The driving source 144 rotates the universal link 143 so as to rotate the vertical screws 141, such that the nuts 142 can move downward along with the furnace lower body 22 and depart from the opening 111 of the top board 11.

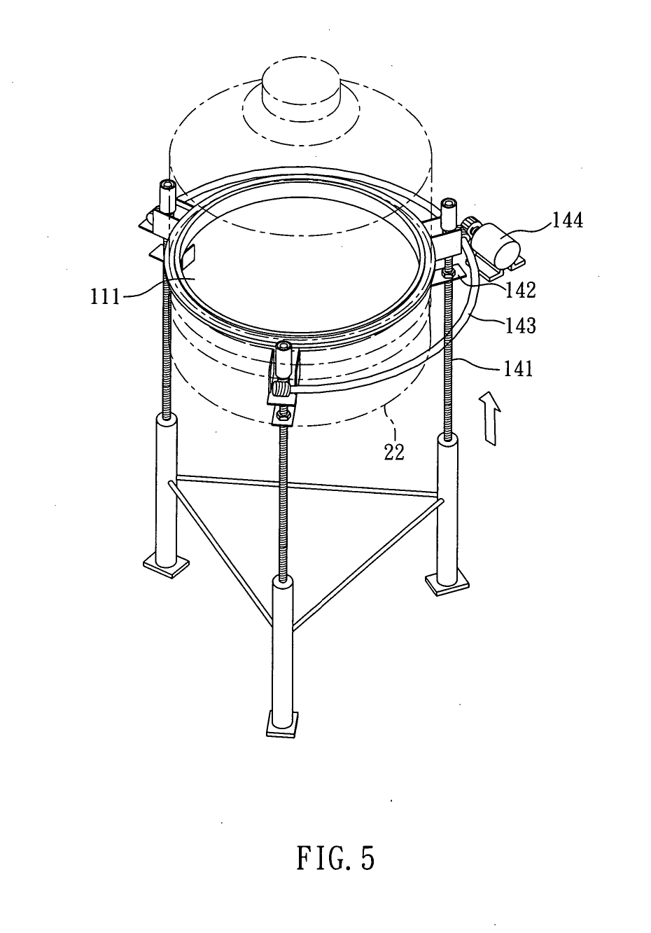

As shown in FIG. 5, the driving source 144 rotates the universal link 143 so as to rotate the vertical screws 141, such that the nuts 142 can move upward along with the furnace lower body 22 and get close to the opening 111 of the top board 11.

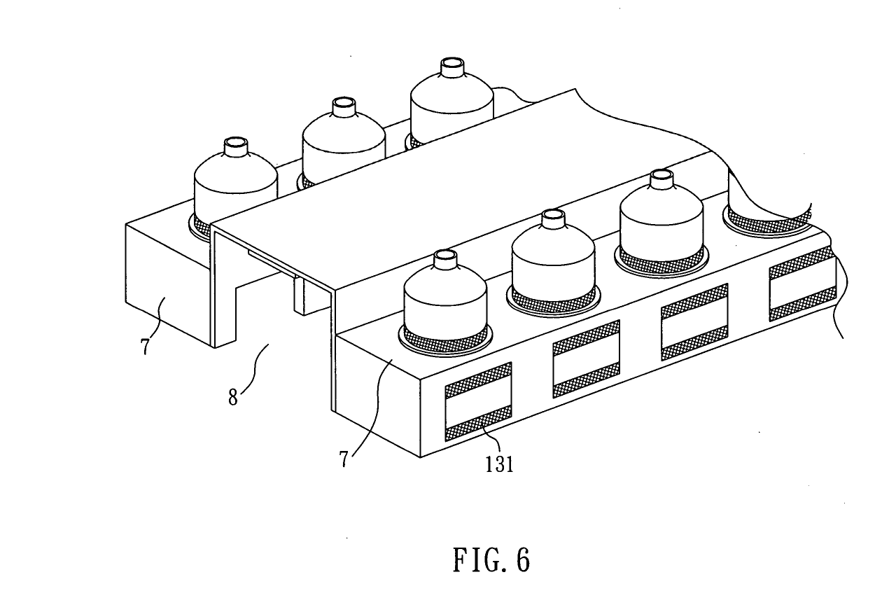

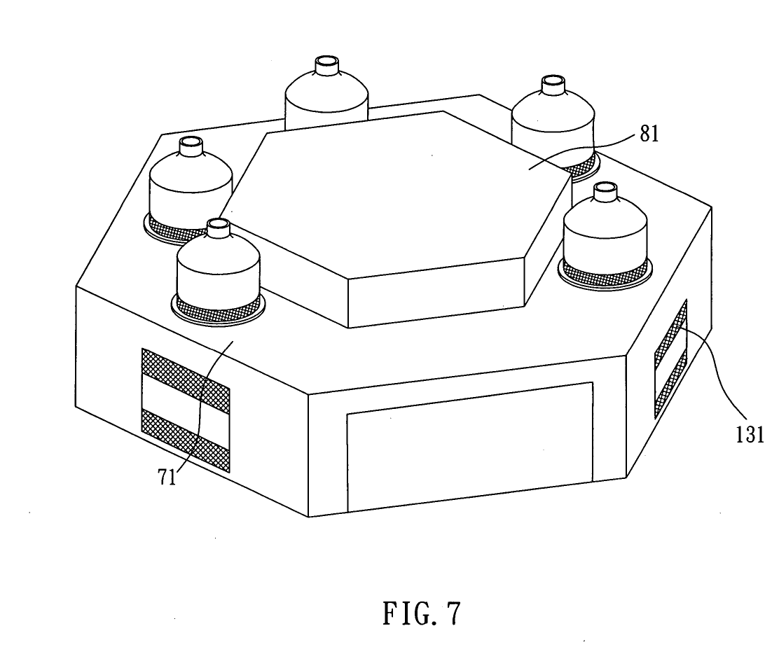

Now referring to FIGS. 6 and 7, schematic views illustrating crystal-growing furnace systems according to a second and a third embodiments of the present invention, the concept in designing the second or third embodiment of the present invention is similar to that of the first embodiment in having an isolated room 7,71 and a controller room 8,81, except that in the second embodiment, as shown in FIG. 6, the isolated room 7 is arranged at two sides of the controller room 8 symmetrically, and that in the third embodiment, as shown in FIG. 7, the isolated room 71 is arranged around the controller room 81. Of course, the crystal-growing furnaces, as described in the three embodiments, can all achieve the objectives of energy saving, cleanness, and safety.

Although the present invention has been explained in relation to its preferred embodiments, it is to be understood that many other possible modifications and variations can be made without departing from the scope of the invention as hereinafter claimed.

What is claimed is:

1. A crystal-growing furnace system, comprising:
an isolated chamber, including a top board and a sidewall, wherein the top board is provided with an opening, the isolated chamber is arranged with a furnace lower body and a lifting device, and wherein the furnace lower body is provided with an upper opening, and the lifting device is provided for selectively moving the furnace lower body upward such that the upper opening gets close to the opening of the top board, or downward and departs from the opening of the top board;
a furnace upper body, being arranged above the top board of the isolated chamber, and provided with a lower opening which matches, correspondingly, the opening of the top board; and
a controller room, being located beside and neighboring to the sidewall of the isolated chamber, where a door is provided on the sidewall, and the door is selectively closed or opened so as to isolate the controller room from the isolated chamber when closed, or to communicate the controller room with the isolated chamber when opened.

2. The crystal-growing furnace system as claimed in claim 1, wherein a reinforced ring is provided around circumference of the opening of the top board at the isolated chamber.

3. The crystal-growing furnace system as claimed in claim 1, wherein the top board of the isolated chamber includes a reinforced concrete frame.

4. The crystal-growing furnace system as claimed in claim 1, wherein the isolated chamber further includes another sidewall on which an air cleaner is provided, such that air inside the isolated chamber can be cleaned through the air cleaner.

5. The crystal-growing furnace system as claimed in claim 1, wherein the lifting device arranged in the isolated room includes at least one vertical screw, at least one nut, at least one universal link, and a driving source; and wherein the at least one nut is engaged, correspondingly, with the at least one vertical screw, the driving source rotates the at least one universal link so as to rotate the at least one vertical screw and to move the furnace lower body.

6. The crystal-growing furnace system as claimed in claim 1, further comprising a heating room including an upper partition, a plurality of side partitions, and a lower partition, wherein the plural side partitions are arrayed around and assembled beneath the upper partition, which are then fixed together to the furnace upper body, whereas the lower partition is fixed to the furnace lower body.

7. The crystal-growing furnace system as claimed in claim 6, wherein the heating room accommodates at least one heater.

8. The crystal-growing furnace system as claimed in claim 6, wherein the heating room has a double-layer structure including an inner insulation layer and an outer warm-keeping layer.

9. The crystal-growing furnace system as claimed in claim 1, wherein the furnace upper body includes an upper furnace wall cooling assembly.

10. The crystal-growing furnace system as claimed in claim 9, wherein the upper furnace wall cooling assembly refers to a spray cooling assembly.

11. The crystal-growing furnace system as claimed in claim 1, wherein the furnace lower body includes a lower furnace wall cooling assembly.

12. The crystal-growing furnace system as claimed in claim 11, wherein the lower furnace wall cooling assembly refers to a spray cooling assembly.
